(19) United States
(12) Patent Application Publication
(10) Pub. No.: US 2006/0255431 A1
(43) Pub. Date: Nov. 16, 2006

(54) Semiconductor wafer

(75) Inventor: Kazuma Sekiya, Tokyo (JP)

Correspondence Address: SMITH, GAMBRELL & RUSSELL, 1850 M STREET, N.W., SUITE 800, WASHINGTON, DC, 20036, US

(73) Assignee: Disco Corporation

(21) Appl. No.: 11/413,149

(22) Filed: Apr. 28, 2006

(30) Foreign Application Priority Data
May 10, 2005 (JP) 2005-137277

(51) Int. Cl. H01L 23/544

(52) U.S. Cl. 257/620

(57) ABSTRACT

A semiconductor wafer comprising a plurality of devices which are formed in a plurality of areas sectioned by streets formed in a lattice pattern on the front surface of a semiconductor substrate, and having test metal patterns formed on the streets, wherein the test metal patterns are formed on one side of the center of each street and connected to a device formed on the other side of the street by a conducting wire laid across the center of the street.

### FIELD OF THE INVENTION

The present invention relates to a semiconductor wafer comprising a plurality of devices, which are formed in a plurality of areas sectioned by streets formed in a lattice pattern on the front surface of a semiconductor substrate, and having test metal patterns formed on the streets.

### DESCRIPTION OF THE PRIOR ART

As known to people of ordinary skill in the art, in the production process of a semiconductor device, individual semiconductor chips are manufactured by cutting a semiconductor wafer comprising devices such as IC's or LSI's which are formed in a plurality of areas sectioned by dividing lines called “streets” arranged in a lattice pattern on the front surface of a substantially disk-like semiconductor substrate along the streets to divide it into the device formed areas.

Most of the above semiconductor wafers have a plurality of test metal patterns called “test element group (TEG)” for testing the function of each device, on the streets. Before the semiconductor wafer having the test metal patterns is divided into individual semiconductor chips, the function of each device is checked by using the test metal patterns. The test metal patterns are then cut and removed simultaneously at the time when the semiconductor wafer is divided into individual semiconductor chips. That is, when the test metal patterns remain, it is possible to detect the constitution of each device from the metal patterns. Therefore, the test metal patterns are removed to protect a company secret.

As a means of dividing a plate-like workpiece such as a semiconductor wafer, JP-A 10-305420 discloses a method in which a pulse laser beam is applied along dividing lines formed on the workpiece to form a groove and the workpiece is divided along the grooves by a mechanical breaking device.

When the grooves are to be formed by applying a laser beam along the streets of the semiconductor wafer having the test metal patterns on the streets, however, there is a problem that the test metal patterns interfere with the laser beam, thereby making it impossible to form grooves uniform in depth. Meanwhile, when the laser beam is applied along the streets while avoiding the test metal patterns, grooves uniform in depth can be formed along the streets in the semiconductor wafer. However, as the test metal patterns remain on the obtained chips, it allows detecting the constitution of each device from the metal patterns remaining on the chip, resulting in the leakage of a company secret.

### SUMMARY OF THE INVENTION

It is an object of the present invention to provide a semiconductor wafer that does not allow the detection of the constitution of a device even if test metal patterns remain on the obtained semiconductor chips.

To attain the above object, according to the present invention, there is provided a semiconductor wafer comprising a plurality of devices which are formed in a plurality of areas sectioned by streets formed in a lattice pattern on the front surface of a semiconductor substrate, and having test metal patterns formed on the streets, wherein

the test metal patterns are formed on one side of the center of each street and connected to a device formed on the other side of the street by a conducting wire laid across the center of the street.

Since the test metal patterns are formed on one side of the center of each street and connected to a device formed on the other side of the street by a conducting wire that is arranged across the center of the street in the semiconductor wafer of the present invention, even when a laser beam is applied along the center of the street, the laser beam is not interfered by the test metal patterns, thereby making it possible to carry out uniform laser processing along the center of the street. Since the conducting wire for connecting the test metal patterns to each device is disconnected by dividing the semiconductor wafer along the centers of the processed streets, even if the test metal patterns remain on the obtained chips, the constitution of each device cannot be detected from the remaining test metal patterns.

### BRIEF DESCRIPTION OF THE DRAWINGS

FIG. 1 is a perspective view of a semiconductor wafer constituted according to the present invention;

FIG. 2 is an enlarged plan view of a principal portion of the semiconductor wafer shown in FIG. 1;

FIG. 3 is an enlarged sectional view of the principal portion of the semiconductor wafer shown in FIG. 1;

FIG. 4 is a perspective view of the semiconductor wafer shown in FIG. 1 put on the surface of a protective tape mounted on an annular frame;

FIG. 5 is a perspective view of the principal portion of a laser beam processing machine for carrying out laser processing on the semiconductor wafer shown in FIG. 1;

FIGS. 6(a) and 6(b) are explanatory diagrams showing the step of carrying out laser processing on the semiconductor wafer shown in FIG. 1 with the laser beam processing machine shown in FIG. 5;

FIG. 7 is an enlarged sectional view of the principal portion of the semiconductor wafer shown in FIG. 1 in which a groove has been formed along the street;

FIG. 8 is a perspective view of a semiconductor chip obtained by dividing the semiconductor wafer shown in FIG. 1 along the streets.

### DETAILED DESCRIPTION OF THE PREFERRED EMBODIMENT

A preferred embodiment of the semiconductor wafer constituted according to the present invention will be described in more detail hereinunder with reference to the accompanying drawings.

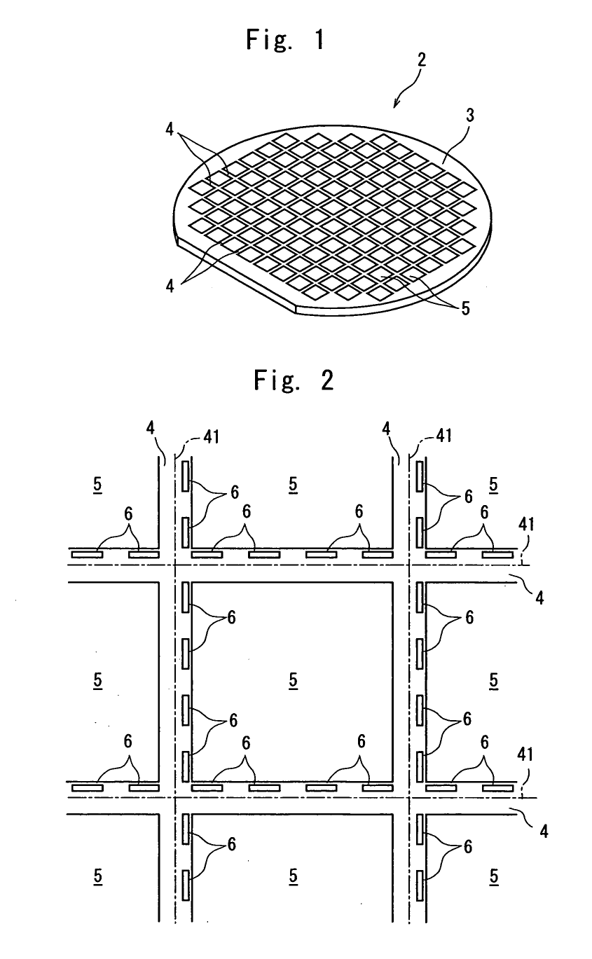

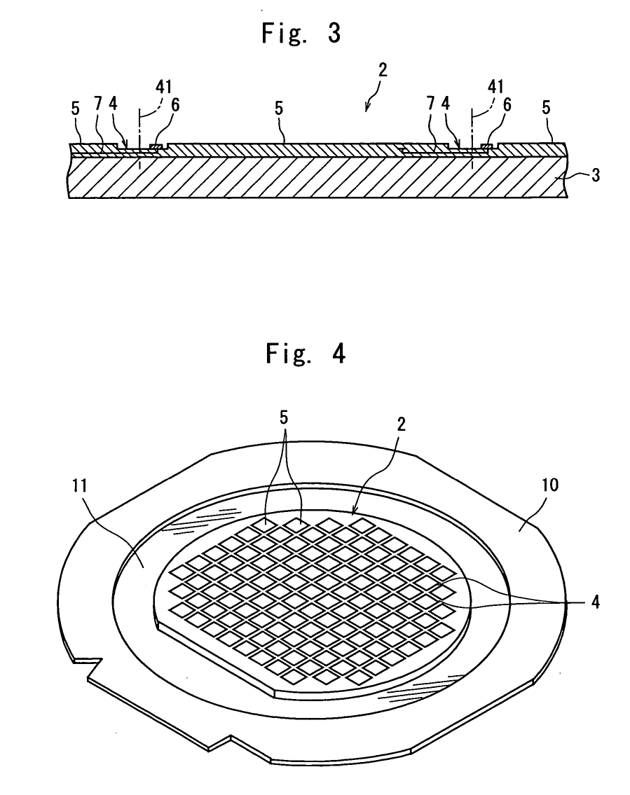

FIG. 1 is a perspective view of a semiconductor wafer constituted according to the present invention, FIG. 2 is an enlarged plan view of the principal portion of the semiconductor wafer shown in FIG. 1, and FIG. 3 is an enlarged sectional view of the principal portion of the semiconductor wafer shown in FIG. 1.

In the semiconductor wafer 2 shown in FIGS. 1 to 3, a plurality of areas are sectioned by streets 4 which are formed in a lattice pattern on the front surface of a semiconductor substrate 3 such as a silicon substrate and the like, and a device 5 is formed in each of the areas. A plurality of test metal patterns 6 are formed on each of the streets 4 of this semiconductor wafer 2, as shown in FIG. 2. The test metal patterns 6 are formed on one side of the center 41 of the street 4. The test metal patterns 6 are connected to a device 5 formed on the other side of the street by a conducting wire 7 laid across the center 41 of the street 4, as shown in FIG. 3.

The semiconductor wafer 2 in the illustrated embodiment is constituted as described above, and the method of dividing the semiconductor wafer 2 along the streets 4 will be described with reference to FIGS. 4 to 8.

In the dividing method shown in FIGS. 4 to 8, the back surface of the above semiconductor wafer 2 is first put on the surface of a protective tape 11 mounted on an annular frame 10 in such a manner that the front surface on which the device 5 is formed faces up, as shown in FIG. 4.

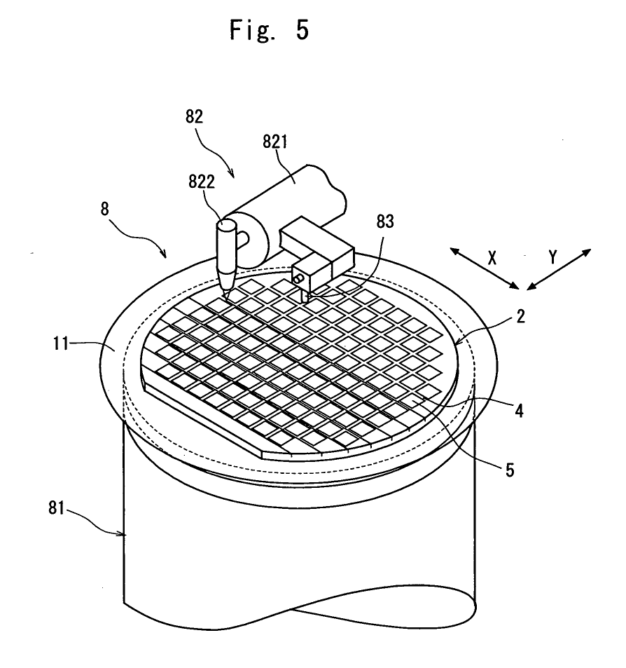

Then, laser processing is carried out to form a groove along the streets 4 formed on the semiconductor wafer 2. This laser processing is carried out by using a laser beam processing machine 8 shown in FIG. 5. The laser beam processing machine 8 shown in FIG. 5 comprises a chuck table 81 for holding a workpiece and a laser beam application means 82 for applying a laser beam to the workpiece held on the chuck table 81. The chuck table 81 is constituted so as to suction-hold the workpiece and is designed to be moved in a processing-feed direction indicated by an arrow X in FIG. 5 by a processing-feed mechanism (not shown) and in an indexing-feed direction indicated by an arrow Y by a indexing-feed mechanism that is not shown.

The above laser beam application means 82 applies a pulse laser beam from a condenser 822 mounted on the end of a cylindrical casing 821 arranged substantially horizontally. The illustrated laser beam processing machine 8 comprises an image pick-up means 83 mounted on the end portion of the casing 821 constituting the above laser beam application means 82, as shown in FIG. 5. This image pick-up means 83 is constituted by an image pick-up device (CCD), etc. and supplies an image signal to a control means that is not shown.

A description will be subsequently given of laser processing for forming a groove along the centers 41 of the streets 4 formed on the semiconductor wafer 2, by using the above laser beam processing machine 8.

The semiconductor wafer 2 supported to the annular frame 10 through the protective tape 11 is first placed on the chuck table 81 of the laser beam processing machine 8 shown in FIG. 5 and suction-held on the chuck table 81. At this point, the semiconductor wafer 2 is held in such a manner that the front surface on which the device 5 is formed faces up. Although the annular frame 10, on which the protective tape 11 affixed to the semiconductor wafer 2 is mounted, is not shown in FIG. 5, the annular frame 10 is fixed by frame holding clamps (not shown) mounted on the chuck table 81.

The chuck table 81 suction-holding the above semiconductor wafer 2 as described above is brought to a position right below the image pick-up means 83 by the processing-feed mechanism that is not shown. After the chuck table 81 is positioned right below the image pick-up means 83, the image pick-up means 83 and the control means (not shown) carry out alignment work for detecting the area to be processed of the semiconductor wafer 2. That is, the image pick-up means 83 and the control means (not shown) carry out image processing such as pattern matching, etc. to align a street 4 formed in a predetermined direction of the semiconductor wafer 2 with the condenser 822 of the laser beam application means 82 for applying a laser beam along the street 4, thereby performing the alignment of a laser beam application position. The alignment of the laser beam application position is also carried out on streets 4 formed on the semiconductor wafer 2 in a direction perpendicular to the above predetermined direction.

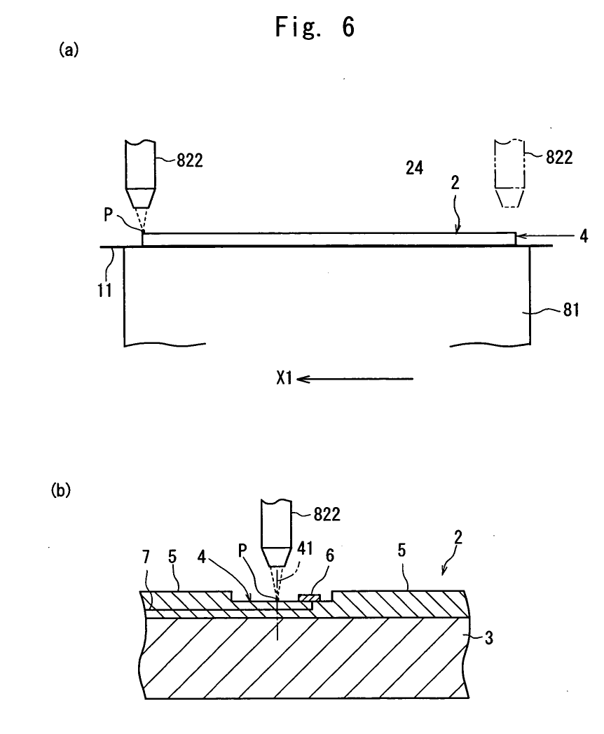

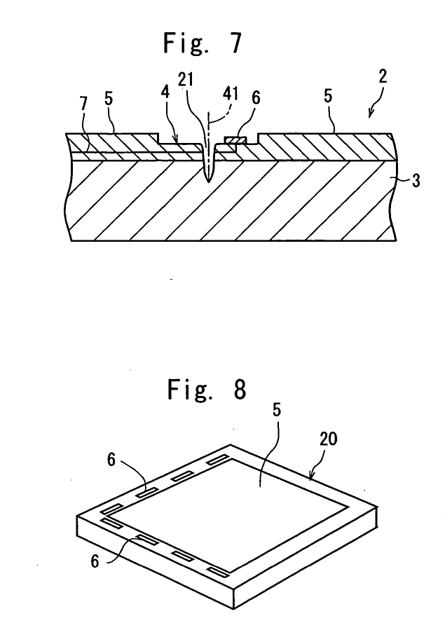

After the street 4 formed on the semiconductor wafer 2 held on the chuck table 81 is detected and the alignment of the laser beam application position is carried out as described above, the chuck table 81 is moved to a laser beam application area where the condenser 822 of the laser beam application means 82 for applying a laser beam is located, so as to bring one end (left end in FIG. 6(a)) of the predetermined street 4 to a position right below the condenser 822, as shown in FIG. 6(a). At this point, the semiconductor wafer 2 is positioned such that the center 41 of the street 4 is located right below the condenser 822, as shown in FIG. 6(b), and the focal point P of a pulse laser beam applied from the condenser 822 is set to a position near the front surface (top surface) of the semiconductor wafer 2. Then, the chuck table 81, that is, the semiconductor wafer 2 is moved in the direction indicated by the arrow X1 in FIG. 6(a) at a predetermined processing-feed rate while the pulse laser beam is applied from the condenser 822 of the laser beam application means 82. When the other end (right end in FIG. 6(a)) of the street 4 reaches a position right below the condenser 822, the application of the pulse laser beam is suspended and the movement of the chuck table 81, that is, the semiconductor wafer 2 is stopped. As a result, as shown in FIG. 7, a groove 21 having a predetermined depth is formed along the center 41 of the street 4. Since the test metal patterns 6 are not formed at the center 41 of the street 4, the pulse laser beam is not interfered by the test metal patterns 6, whereby the groove 21 is formed to the same depth. Since the groove 21 is formed along the center 41 of the street 4, as shown in FIG. 7, the conducting wire 7 for connecting the test metal patterns 6 formed on the street 4 to the device 5 formed on the other side of the street 4 laid across the center 41 of the street 4 is disconnected.

The above laser processing is carried out under the following conditions, for example.
Light source of laser beam: YVO4 laser or YAG laser
Wavelength: 355 nm
Repetition frequency: 30 kHz
Output: 3.5 W
Focal spot diameter: 9.2 μm
Processing-feed rate: 600 mm/sec

After the above laser processing is carried out on all the streets 4 formed in the predetermined direction of the semiconductor wafer 2, the chuck table 81, therefore, the semiconductor wafer 2 is turned at 90°. The above-mentioned laser processing is carried out along all the streets 4 formed in a direction perpendicular to the above predetermined direction on the semiconductor wafer 2. As a result, the groove 21 having a predetermined depth is formed along the centers 41 of all the streets 4 in the semiconductor wafer 2.

The semiconductor wafer 2 having the grooves 21 formed along all the streets 4 is carried to the subsequent dividing step and then, divided along the grooves 21 by a mechanical breaking method. As a result, the semiconductor wafer 2 is divided into individual semiconductor chips 20, as shown in FIG. 8. Although the test metal patterns 6 remain on the thus manufactured semiconductor chips 20, as the conducting wire 7 for connecting the test metal patterns 6 to each device 5 is disconnected as described above, the constitution of the device 5 cannot be detected from the test metal patterns 6.

While the groove is formed along the streets as a means of dividing the semiconductor wafer of the present invention into individual semiconductor chips, the same function and effect are obtained even when the semiconductor wafer of the present invention is divided by other dividing method. For example, a laser beam having permeability for the semiconductor wafer of, for example, a wavelength of 1,064 nm, may be applied to the back surface of the semiconductor wafer along the streets to form a deteriorated layer in the inside of the semiconductor wafer, thereby dividing the semiconductor wafer into individual semiconductor chips along the streets where the deteriorated layer has been formed. Even when the centers of the streets of the semiconductor wafer of the present invention are directly cut with a cutting blade, the cutting blade is not damaged.

What is claimed is:

1. A semiconductor wafer comprising a plurality of devices which are formed in a plurality of areas sectioned by streets formed in a lattice pattern on the front surface of a semiconductor substrate, and having test metal patterns formed on the streets, wherein
the test metal patterns are formed on one side of the center of each street and connected to a device formed on the other side of the street by a conducting wire laid across the center of the street.
